(19) United States
(12) Patent Application Publication
(10) Pub. No.: US 2026/0304653 A1
(43) Pub. Date: Oct. 1, 2026

(54) ELECTRONIC DEVICE AND CHASSIS ASSEMBLY THEREOF

(71) Applicant: PEGATRON CORPORATION, TAIPEI CITY (TW)

(72) Inventor: Jeng-Hong CHIU, TAIPEI CITY (TW)

(21) Appl. No.: 19/573,045

(22) Filed: Mar. 20, 2026

(30) Foreign Application Priority Data
Mar. 25, 2025 (TW) 114111323

(51) Int. Cl. H05K 5/02

(52) U.S. Cl. CPC H05K 5/0221

(57) ABSTRACT

A chassis assembly includes a housing and a locking mechanism. The housing has two slots. The locking mechanism includes two locks corresponding to the two slots respectively. The locks each include a latch, a slider bar, and an insertion sensing member. The latch moves between an extended position and a retracted position. The latch extends into the corresponding slot when at the extended position and retracts from the corresponding slot when at the retracted position. The insertion sensing member is configured to move from an extended position to a retracted position in response to insertion of an object into the corresponding slot. The insertion sensing member of one of the locks blocks a moving path of the slider bar of the other lock when at the extended position and leaves the moving path of the slider bar of the other lock when at the retracted position.

### RELATED APPLICATIONS

This application claims priority to Taiwan Application Serial Number 114111323, filed on Mar. 25, 2025, the disclosure of which is incorporated herein by reference in its entirety.

### TECHNICAL FIELD

The present disclosure relates to an electronic device and a chassis assembly thereof, and in particular, to an electronic device with two removable components.

### BACKGROUND

Some electronic devices are equipped with two removable batteries. For such devices, if the two batteries are removed simultaneously, the devices will be powered off and shut down. However, currently, such electronic devices do not have a mechanism to prevent the two batteries from being removed simultaneously.

### SUMMARY

In view of this, an objective of the present disclosure is to provide an improved chassis assembly and an electronic device, to solve the above-mentioned problems of the related art.

According to an implementation of the present disclosure, a chassis assembly includes a housing and a locking mechanism. The housing has a first slot and a second slot. The locking mechanism is arranged in the housing and includes a first lock and a second lock. The first lock and the second lock are arranged corresponding to the first slot and the second slot respectively and each of the first lock and the second lock include a latch, a slider bar, and an insertion sensing member. The latch is configured to move between a first extended position and a first retracted position. The latch extends into the corresponding first slot or second slot when at the first extended position, and the latch retracts from the corresponding first slot or second slot when at the first retracted position. The slider bar is coupled to the corresponding latch. The slider bar makes the corresponding latch move from the first extended position to the first retracted position when the slider bar moves from a locked position to an unlocked position. The insertion sensing member is slidably arranged in the housing and is configured to move from a second extended position to a second retracted position in response to insertion of an object into the corresponding first slot or second slot. The insertion sensing member of the first lock blocks a moving path of the slider bar of the second lock when at the second extended position and leaves the moving path of the slider bar of the second lock when at the second retracted position. The insertion sensing member of the second lock blocks a moving path of the slider bar of the first lock when at the second extended position and leaves the moving path of the slider bar of the first lock when at the second retracted position.

In one or more implementations of the present disclosure, the first lock and the second lock may be arranged side by side between the first slot and the second slot. The insertion sensing member may include an extension arm, and the extension arm of the insertion sensing member of the first lock may extend toward the slider bar of the second lock and may be configured to block the slider bar of the second lock. The extension arm of the insertion sensing member of the second lock may extend toward the slider bar of the first lock and may be configured to block the slider bar of the first lock.

In one or more implementations of the present disclosure, the slider bar of the first lock may include a boss, and the extension arm of the insertion sensing member of the second lock may include a lug. The lug may be aligned with the boss when the insertion sensing member of the second lock is located at the second extended position, and the lug may be staggered with the boss when the insertion sensing member of the second lock is located at the second retracted position.

In one or more implementations of the present disclosure, the extension arms of the insertion sensing members of the first lock and the second lock may be staggered. Each of the insertion sensing members may further include a guide rib. The extension arm of the insertion sensing member of the first lock may be in sliding fit with the guide rib of the insertion sensing member of the second lock, and the extension arm of the insertion sensing member of the second lock may be in sliding fit with the guide rib of the insertion sensing member of the first lock.

In one or more implementations of the present disclosure, the locking mechanism may further include an elastic member. The elastic member may be arranged between the insertion sensing members of the first lock and the second lock. The elastic member may make the insertion sensing member move to the second extended position when the object is removed from the corresponding first slot or second slot.

In one or more implementations of the present disclosure, the first lock and the second lock may be arranged side by side between the first slot and the second slot. The latch may have a first end and a second end opposite to each other. The first end may face the corresponding first slot or second slot, and the second ends of the latches of the first lock and the second lock may be separated by a gap. A width of the gap may be smaller than a sum of retraction distances of the latches of the first lock and the second lock.

In one or more implementations of the present disclosure, the locking mechanism may further include an elastic member. The elastic member may be arranged between the latches of the first lock and the second lock.

In one or more implementations of the present disclosure, at least one of the first lock and the second lock may further include a positioning member. The positioning member may include a first protrusion, and the slider bar may include a second protrusion. The first protrusion may be configured to interfere with the second protrusion to maintain the slider bar at the unlocked position.

In one or more implementations of the present disclosure, the positioning member may be slidably arranged in the housing and may be configured to extend into the corresponding first slot or second slot, and the first protrusion may be configured to be separated from the second protrusion in response to retracting of the positioning member from the corresponding first slot or second slot.

According to an implementation of the present disclosure, an electronic device includes the foregoing chassis assembly, a first removable component, and a second removable component. The first removable component has a first groove and is configured to be inserted into the first slot of the chassis assembly. The latch of the first lock is fastened into the first groove when the first removable component is inserted into the first slot. The second removable component has a second groove and is configured to be inserted into the second slot of the chassis assembly. The latch of the second lock is fastened into the second groove when the second removable component is inserted into the second slot.

To sum up, the chassis assembly and the electronic device according to the present disclosure include the foregoing locking mechanism, so as to achieve a function of preventing the two removable components from being removed from the electronic device simultaneously. For example, when configured to fix batteries, the locking mechanism can prevent simultaneous removal of two batteries that would result in power loss of the electronic device.

### BRIEF DESCRIPTION OF THE DRAWINGS

To make the foregoing and other objectives, features, advantages, and implementations of the present disclosure more obvious and understandable, the accompanying drawings are described as follows:

FIG. 1 is a three-dimensional view of an electronic device according to an implementation of the present disclosure;

FIG. 2 is a top view of some components of the electronic device shown in FIG. 1 (including hidden lines showing its internal structures), where a removable component is inserted in only one slot of a housing;

FIG. 3 is a three-dimensional view of a locking mechanism of the electronic device shown in FIG. 2;

FIG. 4 is a three-dimensional view of the locking mechanism shown in FIG. 3 with some components hidden;

FIG. 5 and FIG. 6 are top views of some components of the electronic device shown in FIG. 1 (including hidden lines showing its internal structures), where two removable components are inserted into two slots of a housing, respectively, and one of slider bars of a locking mechanism is located at a locked position in FIG. 5 and is located at an unlocked position in FIG. 6; and

FIG. 7 is a partial enlarged view of the electronic device shown in FIG. 5.

### DETAILED DESCRIPTION

To make the description of the present disclosure more detailed and complete, reference may be made to the accompanying drawings and various implementations described below. Components in the drawings are not drawn to scale, but are provided only to illustrate the present disclosure. Many practical details are described below to provide a thorough understanding of the present disclosure. However, a person of ordinary skill in the art should understand that the present disclosure can be implemented without one or more practical details, and therefore, these details should not be used to limit the present disclosure.

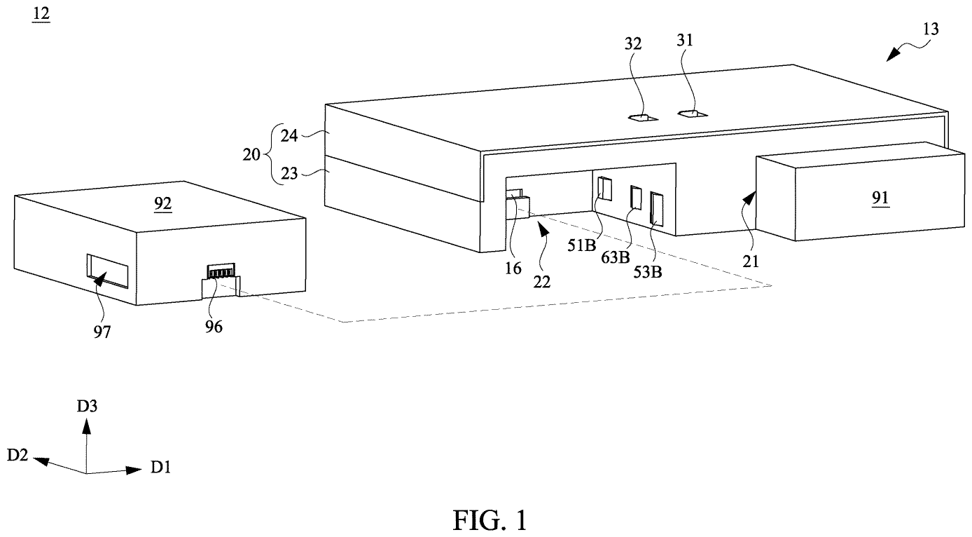

Refer to FIG. 1. FIG. 1 is a three-dimensional view of an electronic device 12 according to an implementation of the present disclosure. As shown in the figure, the electronic device 12 includes a chassis assembly 13 and two removable components 91 and 92. The chassis assembly 13 includes a housing 20, and the housing 20 has two slots 21 and 22. The two slots 21 and 22 are arranged in a first direction D1. The two slots 21 and 22 are configured to receive the two removable components 91 and 92, respectively. The two removable components 91 and 92 can be inserted into (e.g., slid into) the corresponding slot 21 or 22 in a second direction D2, or may be removed from (e.g., slid out of) the slot 21 or 22 in a direction opposite to the second direction D2. The second direction D2 is, for example, perpendicular to the first direction D1. In this implementation, each of the removable components 91 and 92 is a battery, and the battery includes a first electrical connector 96. The chassis assembly 13 further includes two second electrical connectors 16 (only one is shown in FIG. 1), and the two second electrical connectors 16 are arranged in the slots 21 and 22, respectively. When the removable component 91 or 92 is inserted into the corresponding slot 21 or 22, the first electrical connector 96 is connected to the corresponding second electrical connector 16. In another implementation, the removable components 91 and 92 each may alternatively be a removable hard drive, a USB flash drive, a wire connector, or other components.

As shown in FIG. 1, in some implementations, the removable components 91 and 92 may have the same specifications, and therefore the two removable components 91 and 92 can be inserted into the two slots 21 and 22 interchangeably. In some implementations, the housing 20 may be formed by combining two housing components 23 and 24, and one of the housing components 23 is provided with slots 21 and 22.

As shown in FIG. 1, the chassis assembly 13 further includes a locking mechanism. The locking mechanism is arranged in the housing 20 and is configured to fix the removable components 91 and 92 inside the slots 21 and 22 (for example, the locking mechanism may include latches for fixing the removable components 91 and 92), to prevent the removable components 91 and 92 from accidentally disengaging from the slots 21 and 22. The locking mechanism may include two buttons 31 and 32, and the buttons 31 and 32 are at least partially exposed outside the housing 20 (e.g. exposed through holes on the housing 20). A user can operate the buttons 31 and 32 to respectively release the fixation of the removable components 91 and 92, so that the removable components 91 and 92 can be removed from the slots 21 and 22. The locking mechanism featured with the ability to prevent the two removable components 91 and 92 from being simultaneously removed from the electronic device 12. With an example in which the removable components 91 and 92 are batteries, the locking mechanism can prevent simultaneous removal of the two batteries that would result in power loss of the electronic device 12.

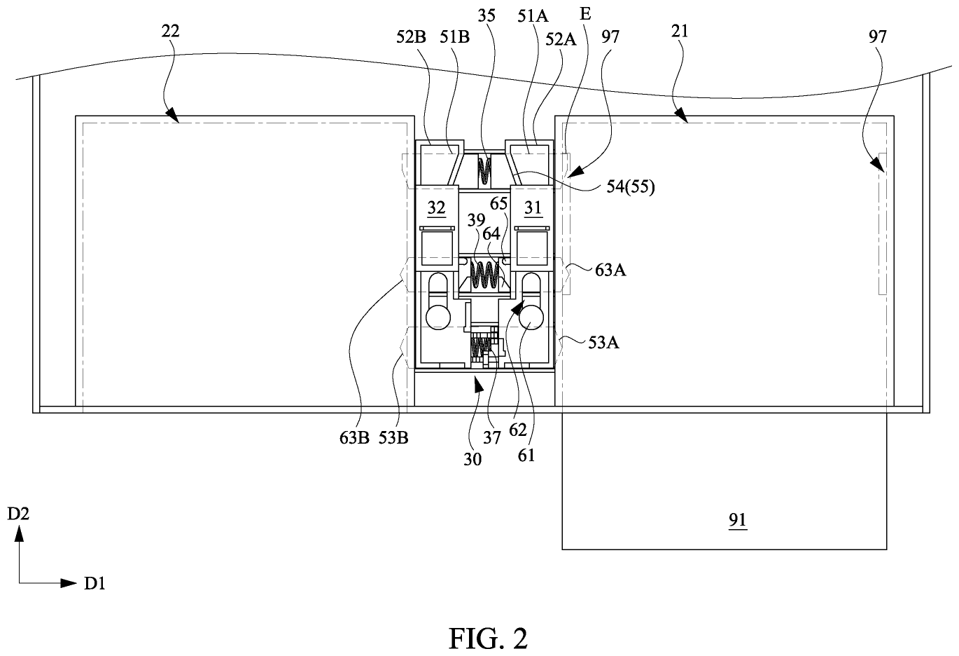

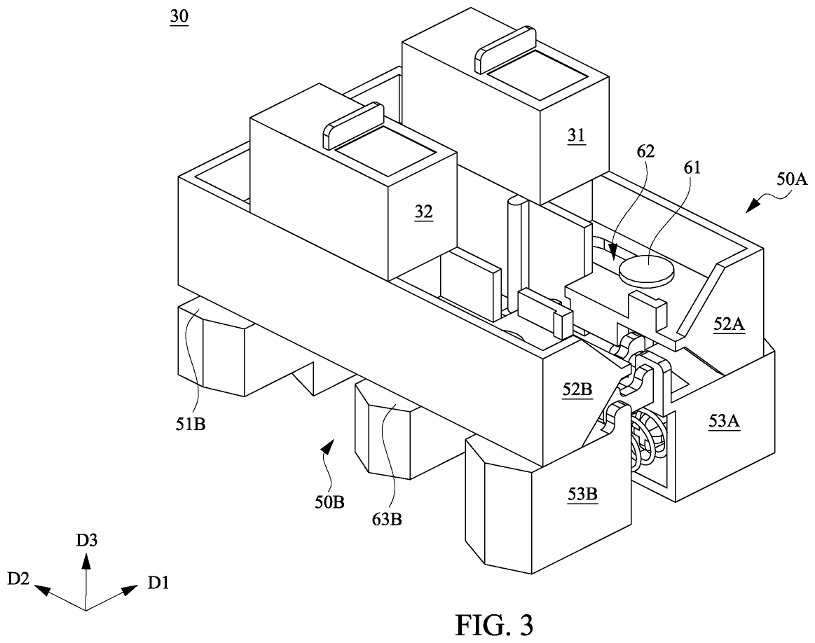

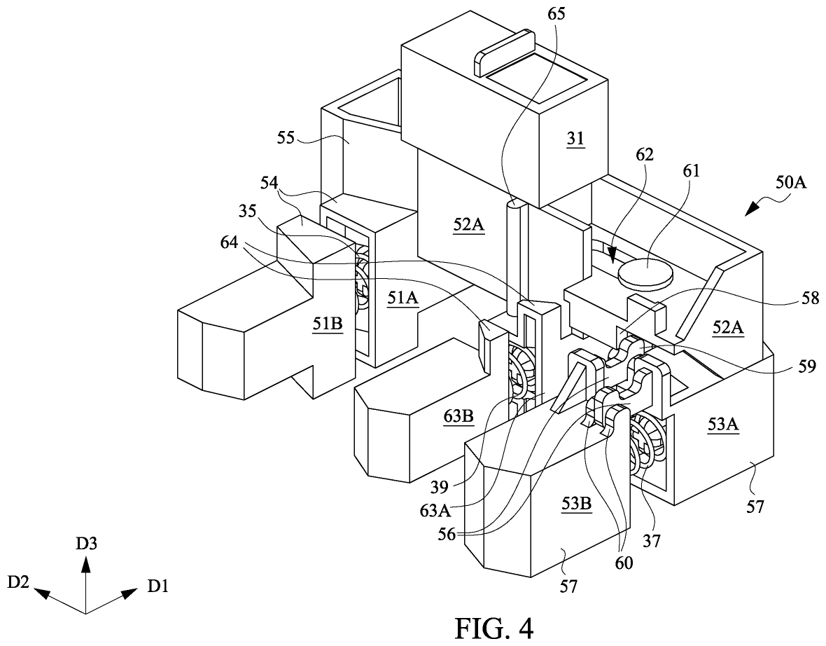

Refer to FIGS. 2-4. FIG. 2 is a top view of the locking mechanism 30, the housing component 23, and the removable component 91 of the electronic device 12 shown in FIG. 1, where inner contours of the slots 21 and 22, an outer contour of the removable component 91, and some covered components of the locking mechanism 30 are denoted by dashed lines. FIG. 3 is a three-dimensional view of the locking mechanism 30 shown in FIG. 2. FIG. 4 is a three-dimensional view of the locking mechanism 30 shown in FIG. 3 with some components hidden. As shown in these figures, the locking mechanism 30 includes two locks 50A and 50B. The two locks 50A and 50B are arranged side by side between the two slots 21 and 22. The two locks 50A and 50B are arranged corresponding to the two slots 21 and 22 respectively and are configured to respectively fix the removable components 91 and 92 inserted into the two slots 21 and 22.

As shown in FIGS. 2-4, the locks 50A and 50B include latches 51A and 51B respectively. The latches 51A and 51B have similar structures or the same structure and are arranged side by side. The latches 51A and 51B are slidably arranged in the housing 20. Specifically, the latches 51A and 51B can reciprocate in the first direction D1 and a direction opposite to the first direction D1. The latches 51A and 51B are configured to move between a first extended position and a first retracted position. The latch 51A extends into the corresponding slot 21 when at the first extended position and retracts from the corresponding slot 21 when at the first retracted position. The latch 51B extends into the corresponding slot 22 when at the first extended position and retracts from the corresponding slot 22 when at the first retracted position. Inner walls of the slots 21 and 22 each may have at least one opening through which the latches 51A and 51B can extend into or retract from the corresponding slots 21 and 22.

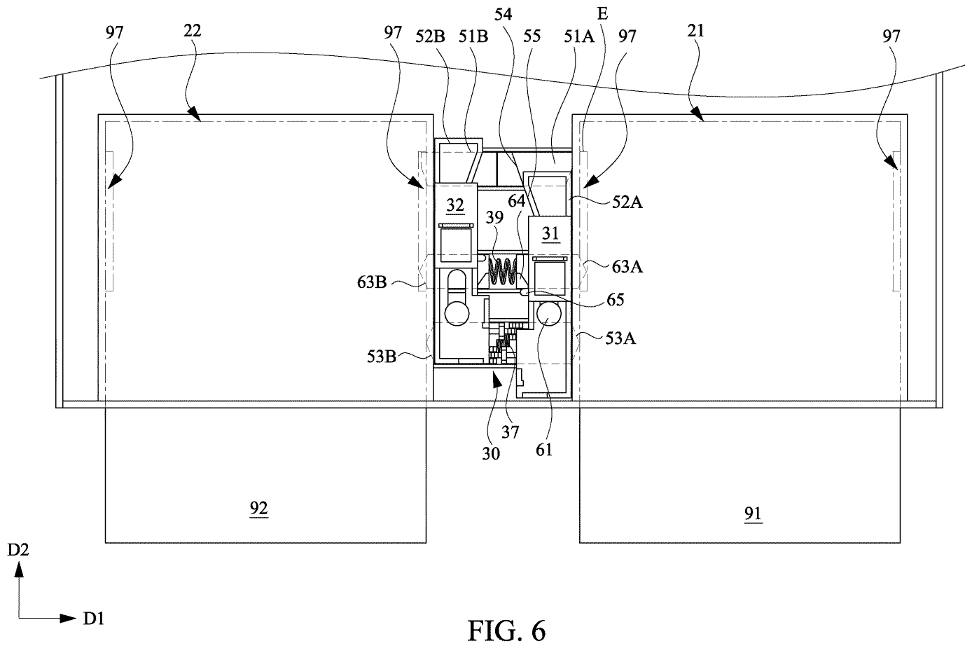

The first extended position is, for example, a position at which the latches 51A and 51B shown in FIG. 2 are located. The ends of the latches 51A and 51B extend into the slots 21 and 22, respectively, when the latches 51A and 51B are at the first extended position. The first retracted position is, for example, a position at which the latch 51A shown in FIG. 6 at the rear is located. The entire latch 51A is located outside the slot 21 when at the first retracted position.

As shown in FIGS. 2-4, the removable components 91 and 92 each have at least one groove 97. The grooves 97 are provided on at least one side surface of the removable components 91 and 92 (FIG. 1 may be also referred to), and positions of the grooves 97 correspond to the latches 51A and 51B. When the removable component 91 or 92 is inserted into the slot 21 or 22 and the corresponding latch 51A or 51B is located at the extended position, the latch 51A or 51B extends into the groove 97, so that the removable component 91 or 92 cannot be removed from the slot 21 or 22. On the other hand, when the latch 51A or 51B is located at the retracted position, the latch 51A or 51B retracts from the groove 97, thereby allowing the removable component 91 or 92 to be removed from the slot 21 or 22.

As shown in FIGS. 2-4, the locks 50A and 50B further include slider bars 52A and 52B respectively. The slider bars 52A and 52B have similar structures or the same structure and are arranged side by side. The slider bars 52A and 52B are slidably arranged in the housing 20. Specifically, the slider bars 52A and 52B can reciprocate in the second direction D2 and a direction opposite to the second direction D2. The buttons 31 and 32 are fixedly connected to the slider bars 52A and 52B respectively, and a user can move the slider bars 52A and 52B by operating the buttons 31 and 32 respectively.

As shown in FIGS. 2-4, the slider bar 52A is mechanically coupled to the corresponding latch 51A. When moving from a locked position to an unlocked position, the slider bar 52A makes the latch 51A move from the first extended position to the first retracted position. Similarly, the slider bar 52B is mechanically coupled to the corresponding latch 51B. When moving from a locked position to an unlocked position, the slider bar 52B makes the latch 51B move from the first extended position to the first retracted position. Accordingly, by operating the buttons 31 and 32, the user can control the latches 51A and 51B to extend or retract respectively, so as to control whether the latches 51A and 51B are fastened to the removable component 91 or 92.

The locked position of the slider bars 52A and 52B is, for example, the positions of the slider bars 52A and 52B shown in FIG. 2, and the unlocked position of the slider bar 52A is, for example, the position of the slider bar 52A shown in FIG. 6 at the rear. The locked position is farther away from entries of the slots 21 and 22 relative to the unlocked position.

As shown in FIGS. 2-4, in some implementations, at least one of the latches 51A and 51B includes a first inclined surface structure 54, and at least one of the slider bars 52A and 52B includes a second inclined surface structure 55. The first inclined surface structure 54 and the second inclined surface structure 55 extend obliquely relative to the second direction D2, and the first inclined surface structure 54 and the second inclined surface structure 55 abut against each other and are in sliding fit with each other. In this way, when the slider bar 52A or 52B moves from the locked position to the unlocked position in the direction opposite to the second direction D2, the fitting between the first inclined surface structure 54 and the second inclined surface structure 55 causes the latch 51A or 51B to be pushed from the first extended position to the first retracted position.

As shown in FIGS. 2-4, in some implementations, the locking mechanism 30 further includes at least one first elastic member 35. The first elastic member 35 is connected to the latches 51A and 51B and is configured to apply a force to the latches 51A and 51B to make the latches 51A and 51B move from the first retracted position to the first extended position. In this implementation, the locking mechanism 30 includes a single first elastic member 35 arranged between the latches 51A and 51B. In this way, during insertion of the removable component 91 or 92 into the corresponding slot 21 or 22, the corresponding latch 51A or 51B can automatically retract first and then pop out to be fastened into the groove 97 of the removable component 91 or 92, thereby completing an automatic locking function.

The first elastic member 35 may be a coil spring as shown in the figure, or may be a flat spring or other types of elastic members. In some implementations, the latches 51A and 51B each have a cavity, and two ends of the first elastic member 35 are inserted into the cavities of the two latches 51A and 51B, respectively. In some implementations, an end of at least one of the latches 51A and 51B has a trapezoidal shape, and the trapezoid has an inclined surface facing the entry of the corresponding slot 21 or 22, and further has a flat surface opposite to the inclined surface. The flat surface is configured to fasten the removable component 91 or 92.

As shown in FIGS. 2-4, the locks 50A and 50B further include insertion sensing members 53A and 53B respectively. The insertion sensing members 53A and 53B have similar structures or the same structure and are arranged side by side. The insertion sensing members 53A and 53B are slidably arranged in the housing 20. Specifically, the insertion sensing members 53A and 53B can reciprocate in the first direction D1 and the direction opposite to the first direction D1. The insertion sensing members 53A and 53B are configured to move between a second extended position and a second retracted position. The insertion sensing member 53A extends into the corresponding slot 21 when at the second extended position and retracts from the corresponding slot 21 when at the second retracted position. The insertion sensing member 53B extends into the corresponding slot 22 when at the second extended position and retracts from the corresponding slot 22 when at the second retracted position. The insertion sensing members 53A and 53B can extend into or retract from the corresponding slots 21 and 22 through the openings on the inner walls of the corresponding slots 21 and 22.

The second extended position is, for example, a position at which the insertion sensing member 53B shown in FIG. 2 is located. An end of the insertion sensing member 53B extends into the corresponding slot 22 when the insertion sensing member 53B is at the second extended position. The second retracted position is, for example, a position at which the insertion sensing member 53A shown in FIG. 2 is located. The entire insertion sensing member 53A is located outside the slot 21 when at the second retracted position.

As shown in FIGS. 2-4, the insertion sensing members 53A and 53B are configured to move from the second extended position to the second retracted position in response to insertion of an object (such as the removable component 91 or 92) into the corresponding slot 21 or 22. In other words, the insertion sensing member 53A or 53B retract from the corresponding slot 21 or 22 in response to the insertion of the object into the corresponding slot 21 or 22. In addition, the insertion sensing member 53A blocks a moving path of the slider bar 52B when at the second extended position and leaves the moving path of the slider bar 52B when at the second retracted position. The insertion sensing member 53B blocks a moving path of the slider bar 52A when at the second extended position and leaves the moving path of the slider bar 52A when at the second retracted position When the moving path of the slider bar 52A is blocked, the slider bar 52A cannot move from the locked position to the unlocked position. When the moving path of the slider bar 52B is blocked, the slider bar 52B cannot move from the locked position to the unlocked position.

As shown in FIGS. 2-4, in some implementations, the insertion sensing members 53A and 53B each include a body 57 and an extension arm 56. The body 57 is a slider configured to extend into or retract from the corresponding slot 21 or 22. The extension arm 56 is connected to the body 57 and extends out from the body 57. The extension arm 56 of the insertion sensing member 53A extends toward the slider bar 52B and is configured to block the slider bar 52B, while the extension arm 56 of the insertion sensing member 53B extends toward the slider bar 52A and is configured to block the slider bar 52A.

As shown in FIG. 4, in some implementations, the slider bar 52A includes a boss 58, and the extension arm 56 of the insertion sensing member 53B includes a lug 59. When the insertion sensing member 53B is located at the second extended position as shown in FIG. 4, the lug 59 is aligned with the boss 58. In this case, the slider bar 52A cannot move from the locked position to the unlocked position. When the insertion sensing member 53B is located at the second retracted position (for example, when the insertion sensing member 53B shown in FIG. 4 moves in the first direction D1 by a distance), the lug 59 and the boss 58 are staggered. In this case, the slider bar 52A can move from the locked position to the unlocked position. The slider bar 52B and the extension arm 56 of the insertion sensing member 53A may also include a boss 58 and a lug 59 respectively, and a positional relationship between the boss and the lug is as described above.

With the foregoing configuration, when the removable component 91 is inserted into the slot 21 but the removable component 92 is not inserted into the slot 22, the insertion sensing member 53B is located at the second extended position, thereby blocking the moving path of the slider bar 52A. In this case, the slider bar 52A is fastened by the insertion sensing member 53B, so that the user cannot operate the button 31 to unlock the removable component 91, and the removable component 91 cannot be removed from the slot 21.

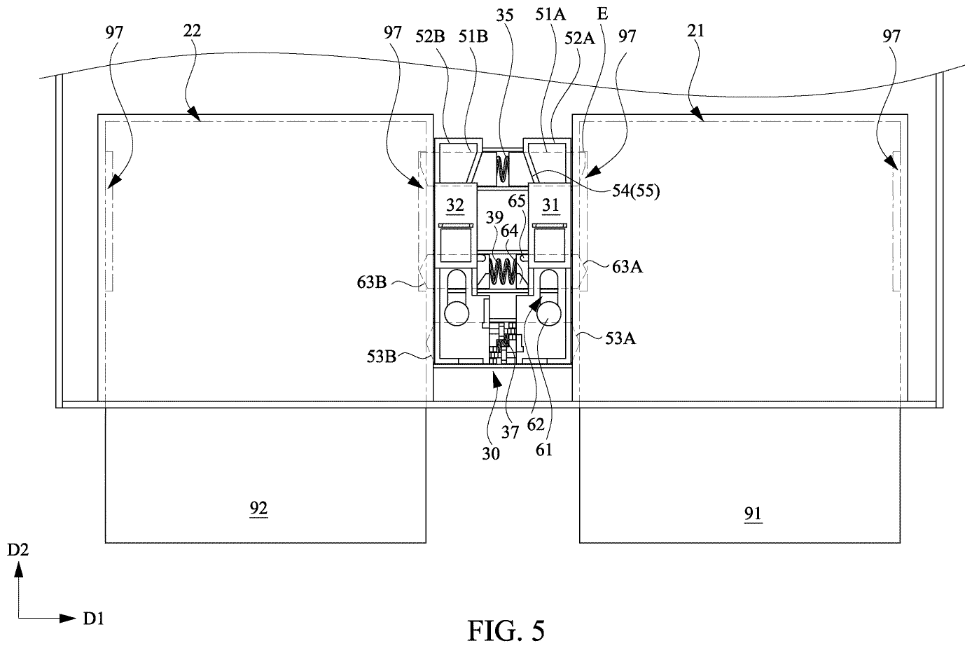

Refer to both FIG. 5 and FIG. 6. As shown in the figure, when the removable component 91 is inserted into the slot 21 and the removable component 92 is inserted into the slot 22, the insertion sensing member 53B moves to the second retracted position, thereby leaving the moving path of the slider bar 52A. In this case, the user can operate the button 31 to unlock the removable component 91. Specifically, the user can move the slider bar 52A from the locked position shown in FIG. 5 to the unlocked position shown in FIG. 6 via the button 31, thereby allowing the removable component 91 to be removed from the slot 21.

Refer back to FIGS. 2-4. In some implementations, the extension arms 56 of the insertion sensing members 53A and 53B are staggered. The insertion sensing members 53A and 53B each further include at least one guide rib 60. The extension arm 56 of the insertion sensing member 53A is in sliding fit with the guide rib 60 of the insertion sensing member 53B, and the extension arm 56 of the insertion sensing member 53B is in sliding fit with the guide rib 60 of the insertion sensing member 53A. In some implementations, at least one of the insertion sensing members 53A and 53B includes a pair of guide ribs 60, and the extension arm 56 is inserted into a gap between the pair of guide ribs 60. The guide ribs 60 can guide the insertion sensing members 53A and 53B to move straight in the first direction D1 or the direction opposite to the first direction D1 and can also strengthen resistance to the sliding of the slider bars 52A and 52B, to prevent the user from forcibly unlocking the removable component 91 or 92.

As shown in FIGS. 2-4, in some implementations, the locking mechanism 30 further includes at least one second elastic member 37. The second elastic member 37 is connected to the insertion sensing members 53A and 53B and is configured to apply a force to the insertion sensing members 53A and 53B to make the insertion sensing members 53A and 53B move from the second retracted position to the second extended position. In this implementation, the locking mechanism 30 includes a single second elastic member 37 arranged between the insertion sensing members 53A and 53B. In this way, when the removable component 91 or 92 is inserted into the corresponding slot 21 or 22, the corresponding insertion sensing member 53A or 53B can automatically retract (move to the second retracted position), and when the removable component 91 or 92 is removed from the corresponding slot 21 or 22, the corresponding insertion sensing member 53A or 53B automatically pops out (return to the second extended position).

The second elastic member 37 may be a coil spring as shown in the figure or may be a flat spring or other types of elastic members. In some implementations, the insertion sensing members 53A and 53B each have a cavity, and two ends of the second elastic member 37 are inserted into the cavities of the insertion sensing members 53A and 53B, respectively. In some implementations, an end of at least one of the insertion sensing members 53A and 53B has two connected inclined surfaces, and an included angle between the two inclined surfaces may be an obtuse angle, to enable the removable component 91 or 92 to be inserted into or removed from the slot 21 or 22.

As shown in FIGS. 2-4, in some implementations, at least one of the locks 50A and 50B further includes at least one fastener 61 (such as a screw), and the corresponding slider bar 52A or 52B has at least one sliding groove 62. The fastener 61 is inserted into the sliding groove 62 and is fixed to the housing 20. The fastener 61 can guide the slider bar 52A or 52B to move straight in the second direction D2 or the direction opposite to the second direction D2.

As shown in FIGS. 4-6, in some implementations, at least one of the locks 50A and 50B further includes a positioning member. In this implementation, the locks 50A and 50B include positioning members 63A and 63B respectively. The positioning members 63A and 63B each include a first protrusion 64, and the slider bars 52A and 52B each include a second protrusion 65. When the slider bars 52A and 52B are located at the locked position, the second protrusion 65 is located on a side of the first protrusion 64 away from the entry of the slot 21 or 22, and when the slider bars 52A and 52B are located at the unlocked position, the second protrusion 65 is located on a side of the first protrusion 64 adjacent to the entry of the slot 21 or 22. The first protrusion 64 is configured to interfere with the second protrusion 65 to maintain the slider bars 52A and 52B at the unlocked position, which enables the user to unlock and remove the removable component 91 or 92 with one hand.

As shown in FIGS. 4-6, the positioning members 63A and 63B have similar structures or the same structure and are arranged side by side. The positioning members 63A and 63B are slidably arranged in the housing 20. Specifically, the positioning members 63A and 63B can reciprocate in the first direction D1 and a direction opposite to the first direction D1. The positioning members 63A and 63B are configured to move between a third extended position and a third retracted position. The positioning member 63A extends into the corresponding slot 21 when at the third extended position and retracts from the corresponding slot 21 when at the third retracted position. The positioning member 63B extends into the corresponding slot 22 when at the third extended position and retracts from the corresponding slot 22 when at the third retracted position. The positioning members 63A and 63B can extend into or retract from the corresponding slots 21 and 22 through the openings on the inner walls of the corresponding slots 21 and 22. In addition, if the removable component 91 or 92 is inserted into the slot 21 or 22, the positioning member 63A or 63B located at the third extended position can extend into the groove 97 of the corresponding removable component 91 or 92.

As shown in FIGS. 4-6, the locking mechanism 30 may further include at least one third elastic member 39. The third elastic member 39 is connected to the positioning members 63A and 63B and is configured to apply a force to the positioning members 63A and 63B to make the positioning members 63A and 63B move from the third retracted position to the third extended position. In this implementation, the locking mechanism 30 includes a single third elastic member 39 arranged between the positioning members 63A and 63B. In this way, the positioning members 63A and 63B can automatically retract (move to the third retracted position) when pressed, and automatically pop out (return to the third extended position, such as the positions shown in FIG. 5 and FIG. 6) when not pressed.

The third elastic member 39 may be a coil spring as shown in the figure or may be a flat spring or other types of elastic members. In some implementations, the positioning members 63A and 63B each have a cavity, and two ends of the third elastic member 39 are inserted into the cavities of the positioning members 63A and 63B, respectively. In some implementations, an end of at least one of the positioning members 63A and 63B has two connected inclined surfaces, and an included angle between the two inclined surfaces may be an obtuse angle, to facilitate inward retraction of the positioning member 63A or 63B when the removable components 91 and 92 are inserted into or removed from the slot 21 or 22.

As shown in FIGS. 4-6, the first protrusions 64 of the positioning members 63A and 63B each may have an inclined surface and a flat surface. The inclined surface is located on a side of the positioning member 63A or 63B away from the entry of the slot 21 or 22, and the flat surface is opposite to the inclined surface. During movement of the slider bar 52A or 52B from the locked position to the unlocked position, the second protrusion 65 of the slider bar 52A or 52B first interfere with the inclined surfaces of the first protrusion 64 of the corresponding positioning member 63A or 63B to push the corresponding positioning member 63A or 63B to the third retracted position. When the slider bar 52A or 52B reaches the unlocked position, the second protrusion 65 completely moves past the first protrusion 64, the corresponding positioning member 63A or 63B returns to the third extended position under the action of the third elastic member 39, and the second protrusion 65 abut against the flat surface of the first protrusion 64. Each second protrusion 65 may have an arc surface or an inclined surface to enable the second protrusion 65 to slide through the inclined surface of the first protrusion 64.

As shown in FIGS. 4-6, in some implementations, the insertion sensing member 53A, the positioning member 63A, and the latch 51A are arranged in the second direction D2, and the slider bar 52A is an element having an elongated shape and extending in the second direction D2. In a third direction D3 perpendicular to the first direction D1 and the second direction D2, the slider bar 52A is stacked on the latch 51A, the positioning member 63A, and the insertion sensing member 53A. In addition, the button 31 may be stacked on the slider bar 52A. An arrangement order of the latch 51A, the positioning member 63A, and the insertion sensing member 53A is not limited to the arrangement order shown in the drawings, but it may be other arrangement orders. When the arrangement order of the latch 51A, the positioning member 63A, and the insertion sensing member 53A is changed to other arrangement orders, the structure of the slider bar 52A needs to be correspondingly adjusted (for example, the positions of the second protrusion 65 and the second inclined surface structure 55 need to be adjusted), and the grooves 97 of the removable components 91 and 92 also need to be correspondingly adjusted. The insertion sensing member 53B, the positioning member 63B, the latch 51B, and the slider bar 52B may have a structural configuration similar to that of the insertion sensing member 53A, the positioning member 63A, the latch 51A, and the slider bar 52A. In some implementations, the housing 20 has at least one sliding groove structure extending in the first direction D1, and the insertion sensing members 53A and 53B, the positioning members 63A and 63B, and the latches 51A and 51B may be arranged in the sliding groove structure. For example, the latches 51A and 51B may be arranged together in a first sliding groove structure, the insertion sensing members 53A and 53B may be arranged together in a second sliding groove structure, and the positioning members 63A and 63B may be arranged together in a third sliding groove structure.

In some implementations, when the removable components 91 and 92 are inserted into the slots 21 and 22, respectively, a procedure for unlocking and removing the removable component 91 is as follows: (1) The user moves the slider bar 52A from the locked position to the unlocked position by operating the button 31, and during the process, the latch 51A is pushed to the first retracted position (retracting from the slot 21 and the groove 97 of the removable component 91) due to the fitting between the first inclined surface structure 54 of the latch 51A and the second inclined surface structure 55 of the slider bar 52A, and the first elastic member 35 is compressed. Furthermore, the positioning member 63A is first pushed to the third retracted position and then returns to the third extended position due to fitting between the first protrusion 64 of the positioning member 63A and the second protrusion 65 of the slider bar 52A, and the first protrusion 64 engages the second protrusion 65 to temporarily maintain the slider bar 52A at the unlocked position. (2) The user removes the removable component 91 in the direction opposite to the second direction D2, and when an edge E of the groove 97 of the removable component 91 passes through the positioning member 63A, the positioning member 63A is pressed to move to the third retracted position (retracting from the slot 21), so that the first protrusion 64 is staggered with and separated from the second protrusion 65. Under the action of the first elastic member 35, the latch 51A returns to the first extended position and makes the slider bar 52A return to the locked position (via the fitting between the first inclined surface structure 54 and the second inclined surface structure 55). In addition, the positioning member 63A also returns to the third extended position under the action of the third elastic member 39. (3) After the removable component 91 is completely removed from the slot 21, the insertion sensing member 53A returns to the second extended position under the action of the second elastic member 37, thereby prohibiting the removable component 92 from being unlocked and removed.

When the removable components 91 and 92 are inserted into the slots 21 and 22 respectively, a procedure for unlocking and removing the removable component 92 is similar to the procedure for unlocking and removing the removable component 91 described above. However, only one of the two removable components 91 and 92 can be unlocked and removed at the same time.

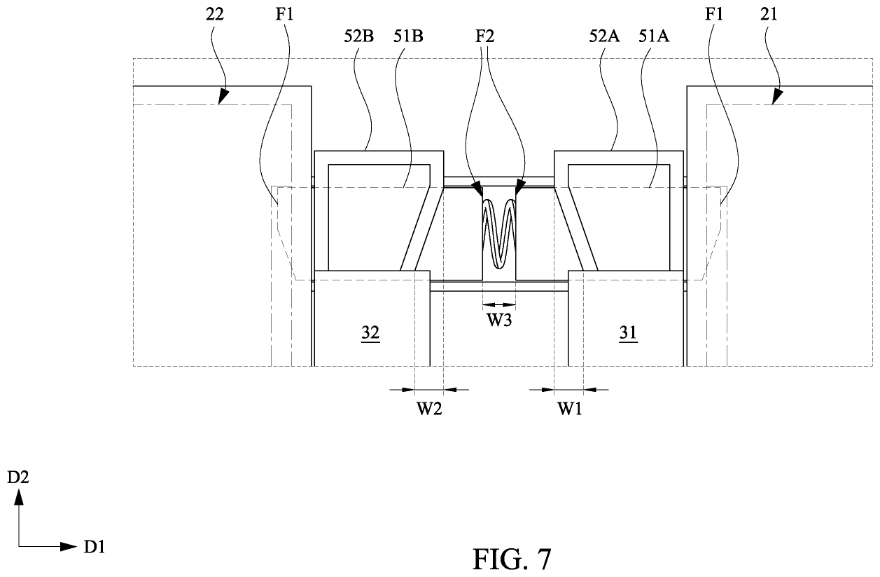

Refer to FIG. 7. FIG. 7 is a partial enlarged view of the electronic device shown in FIG. 5. As shown in the figure, in some implementations, the latches 51A and 51B each have a first end F1 and a second end F2. The first end F1 faces the corresponding slot 21 or 22, and the second end F2 is opposite to the first end F1. The second ends F2 of the latches 51A and 51B are separated by a gap, and a width W3 of the gap is smaller than a sum of a retraction distance W1 of the latch 51A and a retraction distance W2 of the latch 51B. In this way, there is no enough space in the gap between the latches 51A and 51B to allow the latches 51A and 51B to retract to the first retracted position simultaneously, which can prevent the user from pushing the slider bars 52A and 52B to the unlocked position simultaneously.

To sum up, the chassis assembly and the electronic device according to the present disclosure include the foregoing locking mechanism, so as to achieve a function of preventing the two removable components from being removed from the electronic device simultaneously. For example, when configured to fix batteries, the locking mechanism can prevent simultaneous removal of two batteries that would result in power loss of the electronic device.

Although the present disclosure has been disclosed by implementations as above, the implementations are not intended to limit the present disclosure. A person skilled in the art can make various modifications and refinements without departing from the spirit and scope of the present disclosure. Therefore, the protection scope of the present disclosure should be determined by the appended claims.

What is claimed is:

1. A chassis assembly, comprising:
a housing having a first slot and a second slot; and
a locking mechanism arranged in the housing and comprising a first lock and a second lock, wherein the first lock and the second lock are arranged corresponding to the first slot and the second slot, respectively, and each of the first lock and the second lock includes:
a latch configured to move between a first extended position and a first retracted position, wherein the latch extends into a corresponding one of the first slot or the second slot when at the first extended position, and the latch retracts from the corresponding one of the first slot or the second slot when at the first retracted position;
a slider bar coupled to the latch, wherein the slider bar makes the latch move from the first extended position to the first retracted position when the slider bar moves from a locked position to an unlocked position; and
an insertion sensing member slidably arranged in the housing and configured to move from a second extended position to a second retracted position in response to insertion of an object into the corresponding one of the first slot or the second slot, wherein the insertion sensing member of the first lock blocks a moving path of the slider bar of the second lock when at the second extended position and leaves the moving path of the slider bar of the second lock when at the second retracted position, and the insertion sensing member of the second lock blocks a moving path of the slider bar of the first lock when at the second extended position and leaves the moving path of the slider bar of the first lock when at the second retracted position.

2. The chassis assembly of claim 1, wherein the first lock and the second lock are arranged side by side between the first slot and the second slot, the insertion sensing member comprises an extension arm, the extension arm of the insertion sensing member of the first lock extends toward the slider bar of the second lock and is configured to block the slider bar of the second lock, and the extension arm of the insertion sensing member of the second lock extends toward the slider bar of the first lock and is configured to block the slider bar of the first lock.

3. The chassis assembly of claim 2, wherein the slider bar of the first lock comprises a boss, the extension arm of the insertion sensing member of the second lock comprises a lug, the lug is aligned with the boss when the insertion sensing member of the second lock is located at the second extended position, and the lug is staggered with the boss when the insertion sensing member of the second lock is located at the second retracted position.

4. The chassis assembly of claim 2, wherein the extension arms of the insertion sensing members of the first lock and the second lock are staggered, each of the insertion sensing members further comprises a guide rib, the extension arm of the insertion sensing member of the first lock is in sliding fit with the guide rib of the insertion sensing member of the second lock, and the extension arm of the insertion sensing member of the second lock is in sliding fit with the guide rib of the insertion sensing member of the first lock.

5. The chassis assembly of claim 2, wherein the locking mechanism further comprises an elastic member, the elastic member is arranged between the insertion sensing members of the first lock and the second lock, and the elastic member makes the insertion sensing member move to the second extended position when the object is removed from the corresponding one of the first slot or the second slot.

6. The chassis assembly of claim 1, wherein the first lock and the second lock are arranged side by side between the first slot and the second slot, the latch has a first end and a second end opposite to each other, the first end faces the corresponding one of the first slot or the second slot, the second ends of the latches of the first lock and the second lock are separated by a gap, and a width of the gap is smaller than a sum of retraction distances of the latches of the first lock and the second lock.

7. The chassis assembly of claim 6, wherein the locking mechanism further comprises an elastic member, and the elastic member is arranged between the latches of the first lock and the second lock.

8. The chassis assembly of claim 1, wherein at least one of the first lock and the second lock further comprises a positioning member, the positioning member comprises a first protrusion, the slider bar comprises a second protrusion, and the first protrusion is configured to interfere with the second protrusion to maintain the slider bar at the unlocked position.

9. The chassis assembly of claim 8, wherein the positioning member is slidably arranged in the housing and is configured to extend into the corresponding one of the first slot or the second slot, and the first protrusion is configured to be separated from the second protrusion in response to retracting of the positioning member from the corresponding one of the first slot or the second slot.

10. An electronic device, comprising:
the chassis assembly of claim 1;
a first removable component having a first groove and configured to be inserted into the first slot of the chassis assembly, wherein the latch of the first lock is fastened into the first groove when the first removable component is inserted into the first slot; and
a second removable component having a second groove and configured to be inserted into the second slot of the chassis assembly, wherein the latch of the second lock is fastened into the second groove when the second removable component is inserted into the second slot.

11. The electronic device of claim 10, wherein the first lock and the second lock are arranged side by side between the first slot and the second slot, the insertion sensing member comprises an extension arm, the extension arm of the insertion sensing member of the first lock extends toward the slider bar of the second lock and is configured to block the slider bar of the second lock, and the extension arm of the insertion sensing member of the second lock extends toward the slider bar of the first lock and is configured to block the slider bar of the first lock.

12. The electronic device of claim 11, wherein the slider bar of the first lock comprises a boss, the extension arm of the insertion sensing member of the second lock comprises a lug, the lug is aligned with the boss when the insertion sensing member of the second lock is located at the second extended position, and the lug is staggered with the boss when the insertion sensing member of the second lock is located at the second retracted position.

13. The electronic device of claim 11, wherein the extension arms of the insertion sensing members of the first lock and the second lock are staggered, each of the insertion sensing members further comprises a guide rib, the extension arm of the insertion sensing member of the first lock is in sliding fit with the guide rib of the insertion sensing member of the second lock, and the extension arm of the insertion sensing member of the second lock is in sliding fit with the guide rib of the insertion sensing member of the first lock.

14. The electronic device of claim 11, wherein the locking mechanism further comprises an elastic member, the elastic member is arranged between the insertion sensing members of the first lock and the second lock, and the elastic member makes the insertion sensing member move to the second extended position when the object is removed from the corresponding one of the first slot or the second slot.

15. The electronic device of claim 10, wherein the first lock and the second lock are arranged side by side between the first slot and the second slot, the latch has a first end and a second end opposite to each other, the first end faces the corresponding one of the first slot or the second slot, the second ends of the latches of the first lock and the second lock are separated by a gap, and a width of the gap is smaller than a sum of retraction distances of the latches of the first lock and the second lock.

16. The electronic device of claim 15, wherein the locking mechanism further comprises an elastic member, and the elastic member is arranged between the latches of the first lock and the second lock.

17. The electronic device of claim 10, wherein at least one of the first lock and the second lock further comprises a positioning member, the positioning member comprises a first protrusion, the slider bar comprises a second protrusion, and the first protrusion is configured to interfere with the second protrusion to maintain the slider bar at the unlocked position.

18. The electronic device of claim 17, wherein the positioning member is slidably arranged in the housing and is configured to extend into the corresponding one of the first slot or the second slot, and the first protrusion is configured to be separated from the second protrusion in response to retracting of the positioning member from the corresponding one of the first slot or the second slot.
